(19) United States
(12) Patent Application Publication
(10) Pub. No.: US 2021/0008956 A1
(43) Pub. Date: Jan. 14, 2021

(54) VEHICLE TEMPERATURE CONTROL SYSTEM AND METHOD OF CONTROLLING THE SAME

(71) Applicants: HYUNDAI MOTOR COMPANY, Seoul (KR); KIA MOTORS CORPORATION, Seoul (KR)

(72) Inventors: Min Jae LEE, Seoul (KR); Tae Han KIM, Seoul (KR); Tae Woong LIM, Hwaseong-si (KR); Ho Gyu CHOI, Yongin-si (KR); Jeong Yung LEE, Incheon (KR); Hong Rok SHIM, Yongin-si (KR); Sang Min JO, Pyeongtaek-si (KR); Seung Ho LEE, Seoul (KR)

(73) Assignees: HYUNDAI MOTOR COMPANY, Seoul (KR); KIA MOTORS CORPORATION, Seoul (KR)

(21) Appl. No.: 16/690,828

(22) Filed: Nov. 21, 2019

(30) Foreign Application Priority Data
Jul. 8, 2019 (KR) 10-2019-0082051

(51) Int. Cl. B60H 1/00; H01L 35/04; H01L 23/36; B60N 2/56

(52) U.S. Cl. CPC B60H 1/00292; B60H 1/00285; B60N 2/5678; H01L 23/36; H01L 35/04

(57) ABSTRACT

A vehicle temperature control system includes: an air conditioning unit configured to cool and heat an interior of a vehicle; a first thermoelectric module mounted in a steering wheel of the vehicle and configured to be selectively heated or cooled; a second thermoelectric module mounted in a seat of the vehicle and configured to be selectively heated or cooled; and an integrated control unit configured to integrally control the air conditioning unit, the first thermoelectric module, and the second thermoelectric module, thereby obtaining an advantageous effect of improving temperature control efficiency and energy efficiency.

### CROSS-REFERENCE TO RELATED APPLICATION

This application claims priority to and the benefit of Korean Patent Application No. 10-2019-0082051, filed on Jul. 8, 2019, the entire contents of which are incorporated herein by reference.

### FIELD

The present disclosure relates to a vehicle temperature control system and a method of controlling the same to improve temperature control efficiency and energy efficiency.

### BACKGROUND

The statements in this section merely provide background information related to the present disclosure and may not constitute prior art.

Because a vehicle temperature control system and a method of controlling the same, which use an air conditioning device, control a temperature based on a temperature of air, a large amount of energy consumption is required, and it takes a lot of time for a user to sense a change in temperature. As a result, there is a limitation in that it is difficult to improve temperature control efficiency and energy efficiency to a certain level.

Recently, a temperature control system has been developed, in which a thermoelectric module capable of heating and cooling is brought into direct contact with a user.

In general, the thermoelectric module is manufactured by connecting electrodes to P-type thermoelectric materials and N-type thermoelectric materials on a substrate and has an advantage of having a low thermal loss and performing quick temperature control.

However, we have discovered that because the thermoelectric module in the related art controls a temperature regardless of a predetermined temperature of an air conditioning device of a vehicle, there occurs a deviation between the predetermined temperature and a sensible temperature actually sensed by an occupant (e.g., a state in which the sensible temperature is higher or lower than the predetermined temperature), and as a result, there is a problem in that an occupant's comfort is decreased and unnecessary power consumption is increased.

Therefore, recently, various types of research are conducted to improve the occupant's comfort and improve energy efficiency, but the research result is still insufficient.

### SUMMARY

The present disclosure provides a vehicle temperature control system and a method of controlling the same, which are capable of improving an occupant's comfort and improving temperature control efficiency and energy efficiency.

The present disclosure also improves convenience of temperature control by integrally controlling a temperature of an air conditioning unit, a temperature of a steering wheel, and a temperature of a seat.

In one form of the present disclosure, a vehicle temperature control system includes: an air conditioning unit configured to cool and heat an interior of a vehicle; a first thermoelectric module mounted in a steering wheel of the vehicle and configured to be selectively heated or cooled; a second thermoelectric module mounted in a seat of the vehicle and configured to be selectively heated or cooled; and an integrated control unit configured to integrally control the air conditioning unit, the first thermoelectric module, and the second thermoelectric module.

This configuration is intended to improve an occupant's comfort and improve temperature control efficiency and energy efficiency.

That is, because a temperature of a steering wheel and a temperature of a seat are individually controlled regardless of a predetermined temperature of an air conditioning device of a vehicle in the related art, there occurs a deviation between the predetermined temperature and a sensible temperature actually sensed by an occupant (e.g., a state in which the sensible temperature is higher or lower than the predetermined temperature), and as a result, there is a problem in that an occupant's comfort is decreased and unnecessary power consumption is increased.

However, according to the present disclosure, the temperature of the air conditioning unit, the temperature of the steering wheel, and the temperature of the seat are integrally controlled, thereby obtaining an advantageous effect of improving an occupant's comfort and improving temperature control efficiency and energy efficiency.

Particularly, the first thermoelectric module and the second thermoelectric module are controlled based on the thermal demand value for the fully automatic temperature control of the air conditioning unit, thereby obtaining an advantageous effect of quickly establishing a comfortable traveling environment and reducing or minimizing unnecessary power consumption.

As an example, the first thermoelectric module includes a first thermoelectric material layer mounted in the steering wheel, a thermal diffusion layer configured to cover the first thermoelectric material layer, a heat pipe provided below the first thermoelectric material layer, and a heat sink provided below the heat pipe.

As described above, the heat sink is provided below the heat pipe such that the heat exceeding the heat capacity of the heat pipe is discharged to the outside of the steering wheel via the heat sink, thereby obtaining an advantageous effect of improving performance of cooling the first thermoelectric material layer.

That is, at the time of cooling the surface of the steering wheel by applying the current to the first thermoelectric material layer, one side of the first thermoelectric material layer (e.g., an upper portion of the first thermoelectric material layer) is cooled, and the other side of the first thermoelectric material layer (e.g., a lower portion of the first thermoelectric material layer) is heated.

In this case, the heat at the lower portion (high-temperature part) of the first thermoelectric material layer is absorbed by an armature in the steering wheel, but it is difficult to sufficiently absorb the heat, which is generated at the lower portion of the first thermoelectric material layer, only with the heat capacity of the armature, and as a result, there is a problem in that the performance of cooling the first thermoelectric material layer deteriorates.

In contrast, according to the present disclosure, the heat sink is provided below the first thermoelectric material layer, and the heat sink may increase the heat capacity that may be insufficiently provided only by the armature in the steering wheel. As a result, it is possible to obtain an advantageous effect of increasing an operating time for cooling the first thermoelectric material layer and improving cooling performance by reducing or minimizing a rate at which the heat of the high-temperature part of the first thermoelectric material layer is transferred to the surface of the steering wheel (the upper portion of the first thermoelectric material layer).

Particularly, the heat pipe is made of a phase change material (PCM).

In addition, the first thermoelectric module may include a felt layer formed to cover an upper portion of the thermal diffusion layer.

The second thermoelectric module includes a first layer provided in a seat, a second thermoelectric material layer disposed on an upper surface of the first layer, a second layer disposed to cover the second thermoelectric material layer, and a flexible support layer disposed between the first layer and the second layer and configured to support the unit thermoelectric material.

Particularly, the first layer is made of a phase change material (PCM).

The flexible support layer is provided between the first layer and the second layer to elastically support the second thermoelectric material layer so that the second thermoelectric material layer may be bent by the contact with a user's body. As an example, the flexible support layer is made of a polydimethylsiloxane (PDMS) material. As described above, since the second thermoelectric material layer is elastically supported by the flexible support layer made of polydimethylsiloxane (PDMS) which is one of the flexible materials, the second thermoelectric material layer may be freely bent by the contact with the user's body.

The integrated control unit controls a temperature of the first thermoelectric module and a temperature of the second thermoelectric module based on the thermal demand value for performing the fully automatic temperature control (FATC) of the air conditioning unit.

Particularly, based on a predetermined reference thermal demand range, the integrated control unit is configured to cool or heat the first thermoelectric module and the second thermoelectric module based on the thermal demand value.

As an example, the integrated control unit is configured to cool the first thermoelectric module and the second thermoelectric module when the thermal demand value for the fully automatic temperature control is below the predetermined reference thermal demand range. As another example, the integrated control unit is configured to heat the first thermoelectric module and the second thermoelectric module when the thermal demand value for the fully automatic temperature control is above the predetermined reference thermal demand range.

In another exemplary form, the present disclosure provides a method of controlling the vehicle temperature control system that includes an air conditioning unit configured to cool and heat an interior of a vehicle, a first thermoelectric module mounted in a steering wheel of a vehicle and configured to be selectively heated or cooled, and a second thermoelectric module mounted in a seat of the vehicle and configured to be selectively heated or cooled. In particular, the method includes : a measurement step of measuring the thermal demand (Td) value for the fully automatic temperature control (FATC) of the air conditioning unit; and a control step of integrally controlling the air conditioning unit, the first thermoelectric module, and the second thermoelectric module based on the thermal demand value.

More specifically, in the control step, a temperature of the first thermoelectric module and a temperature of the second thermoelectric module are controlled based on the thermal demand value.

Particularly, the control step is configured to cool or heat the first thermoelectric module and second thermoelectric module based on the thermal demand value detected based on a predetermined reference thermal demand range.

As an example, in the control step, the first thermoelectric module and the second thermoelectric module are controlled to be cooled when the thermal demand value for the fully automatic temperature control is below the predetermined reference thermal demand range, and the first thermoelectric module and the second thermoelectric module are controlled to be heated when the thermal demand value for the fully automatic temperature control is above the predetermined reference thermal demand range.

In one form, in the control step, when the operating time (current applying time) for cooling and heating the first thermoelectric module and the second thermoelectric module is above the predetermined operating time range, the operation of the first thermoelectric module and the operation of the second thermoelectric module are stopped. As described above, the operation of the first thermoelectric module and the operation of the second thermoelectric module are stopped when the operating time for cooling and heating the first thermoelectric module and the second thermoelectric module is above the predetermined operating time range, thereby obtaining an advantageous effect of preventing the first thermoelectric module and the second thermoelectric module from being overheated and overcooled and thus inhibiting or minimizing injuries to the occupant (e.g., burns) caused by overheating.

More particularly, in the control step, the operation of cooling the first thermoelectric module is intermittently turned on or off.

This configuration is based on the fact that the heat pipe and the heat sink, which treat and discharge the heat generated at the high-temperature part of the first thermoelectric module, have restrictive heat capacities due to the structural restriction of the steering wheel. The operation of cooling the first thermoelectric module is intermittently turned on or off, thereby obtaining an advantageous effect of minimizing deterioration in cooling performance caused by deterioration in heat discharging properties of the first thermoelectric module.

According to the present disclosure as described above, it is possible to obtain an advantageous effect of improving an occupant's comfort and improving temperature control efficiency and energy efficiency.

In particular, according to the present disclosure, a temperature of the air conditioning unit, a temperature of a steering wheel, and a temperature of the seat are integrally controlled, thereby obtaining an advantageous effect of minimizing unnecessary power consumption, enabling quick temperature control, and further improving an occupant's comfort.

Further areas of applicability will become apparent from the description provided herein. It should be understood that the description and specific examples are intended for purposes of illustration only and are not intended to limit the scope of the present disclosure.

### DRAWINGS

In order that the disclosure may be well understood, there will now be described various forms thereof, given by way of example, reference being made to the accompanying drawings, in which:

FIG. 1 is a view for explaining a vehicle temperature control system according to one form of the present disclosure;

FIGS. 2 and 3 are views for explaining a first thermoelectric module as a vehicle temperature control system according to another form of the present disclosure;

FIGS. 4 and 5 are views for explaining a second thermoelectric module as a vehicle temperature control system according to one form of the present disclosure;

FIG. 6 is a block diagram illustrating a method of controlling the vehicle temperature control system according to one form of the present disclosure;

FIGS. 7 and 8 are views for explaining a process of operating the second thermoelectric module, as a method of controlling the vehicle temperature control system according to one form of the present disclosure; and

FIGS. 9 and 10 are views for explaining a process of operating the first thermoelectric module, as the method of controlling the vehicle temperature control system according to another form of the present disclosure.

The drawings described herein are for illustration purposes only and are not intended to limit the scope of the present disclosure in any way.

### DETAILED DESCRIPTION

The following description is merely exemplary in nature and is not intended to limit the present disclosure, application, or uses. It should be understood that throughout the drawings, corresponding reference numerals indicate like or corresponding parts and features.

Hereinafter, exemplary forms of the present disclosure will be described in detail with reference to the accompanying drawings, but the present disclosure is not restricted or limited by the exemplary forms. For reference, like reference numerals denote substantially identical elements in the present description, the description may be made under this rule by incorporating the contents illustrated in other drawings, and the contents repeated or determined as being obvious to those skilled in the art may be omitted.

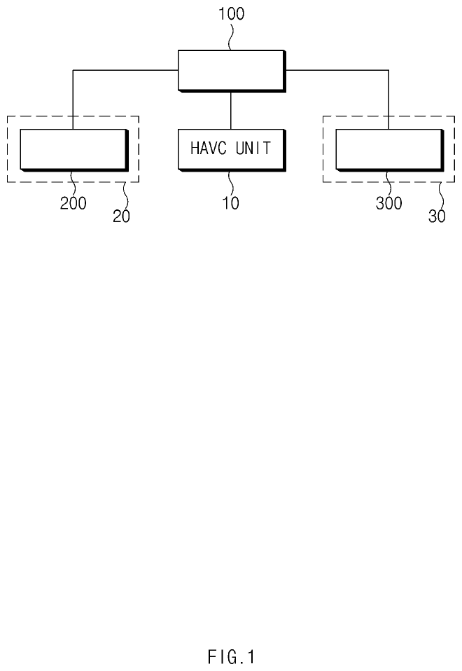

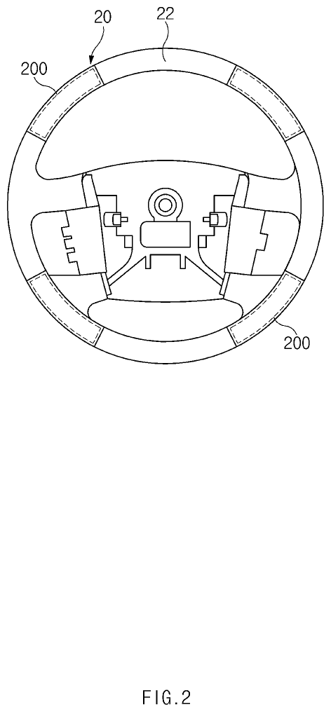

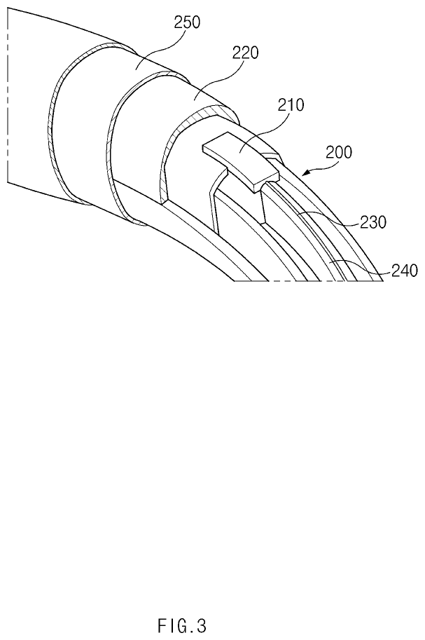

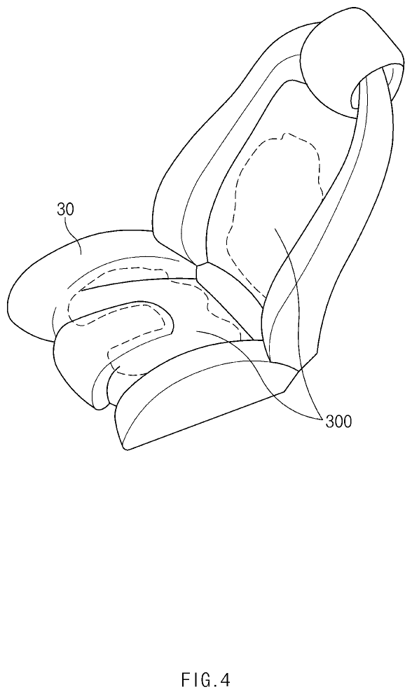

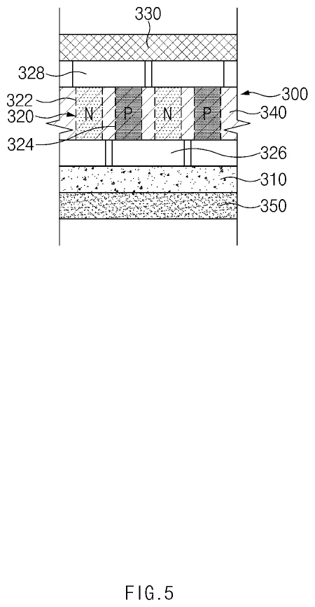

FIG. 1 is a view for explaining a vehicle temperature control system according to one form of the present disclosure, FIGS. 2 and 3 are views for explaining a first thermoelectric module as a vehicle temperature control system according to one form of the present disclosure, and FIGS. 4 and 5 are views for explaining a second thermoelectric module as a vehicle temperature control system according to another form of the present disclosure.

Referring to FIGS. 1 to 5, a vehicle temperature control system according to the present disclosure includes: an air conditioning unit 10 configured to cool and heat an interior of a vehicle; a first thermoelectric module 200 mounted in a steering wheel 20 of the vehicle and configured to be selectively heated or cooled; a second thermoelectric module 300 mounted in a seat of the vehicle and configured to be selectively heated or cooled; and an integrated control unit 100 configured to integrally control the air conditioning unit 10, the first thermoelectric module 200, and the second thermoelectric module 300.

The air conditioning unit (HAVC UNIT) is configured to adjust an indoor temperature of the vehicle (e.g., cooling or heating) based on an HAVC (heat, air ventilation and cooling) device.

As an example, the temperature control using the air conditioning unit is performed by the integrated control unit 100 based on a thermal demand (Td) value which is a control factor of fully automatic temperature control (FATC).

For reference, the thermal demand value refers to a default value (control factor) used for performing the fully automatic temperature control by the air conditioning unit. The thermal demand value may be determined by calculating the amount of change in accordance with the change in inside air temperature (indoor temperature) and outside air temperature. As an example, based on the thermal demand value, a direction of air blowing, the amount of air blowing, an indoor temperature, and a state of introducing outside air may be automatically controlled.

The first thermoelectric module 200 is mounted in the steering wheel 20 of the vehicle and configured to be selectively heated or cooled by being controlled by the integrated control unit 100.

As an example, the first thermoelectric module 200 is mounted along a rim 22 of the steering wheel 20.

The first thermoelectric module 200 may have various structures capable of being heated or cooled by being supplied with power, but the present disclosure is not restricted or limited by the structure of the first thermoelectric module 200.

As an example, the first thermoelectric module 200 includes a first thermoelectric material layer 210 mounted in the steering wheel 20, a thermal diffusion layer 220 formed to cover the first thermoelectric material layer 210, a heat pipe 230 provided below the first thermoelectric material layer 210, and a heat sink 240 provided below the heat pipe 230.

The first thermoelectric material layer 210 may be formed by arranging, in a predetermined pattern, multiple unit thermoelectric materials in which N-type thermoelectric materials (not illustrated) and P-type thermoelectric materials (not illustrated), which have opposite polarities, are connected with electrodes.

Particularly, the first thermoelectric material layer 210 is formed to have a flexible structure that may be bent along a surface curve of the steering wheel 20.

As an example, the first thermoelectric material layer 210 may be formed by forming an electrode pattern on an elastic layer (made of, for example, rubber or polyurethane), and patterning (e.g., screen printing or coating) the thermoelectric materials so that the thermoelectric materials are connected to the electrodes.

The thermal diffusion layer 220 is provided to diffuse cold air or warm air generated by the first thermoelectric material layer 210 and formed to cover an upper portion of the first thermoelectric material layer 210.

As an example, an aluminum profile having a thin film structure may be used as the thermal diffusion layer 220.

The heat pipe 230 is provided to absorb heat generated at the first thermoelectric material layer 210.

As an example, the heat pipe 230 may be formed in the form of a wire and disposed below the first thermoelectric material layer 210.

The heat pipe 230 may be made of various materials capable of absorbing heat generated at the first thermoelectric material layer 210, but the present disclosure is not restricted or limited by the material of the heat pipe 230. Particularly, the heat pipe 230 is made of a phase change material (PCM).

The heat sink is provided to discharge the heat (the heat generated at the first thermoelectric material layer 210), which exceeds a heat capacity of the heat pipe 230, to the outside of the steering wheel 20. As an example, the heat sink 240 is disposed to be in close contact with a lower portion of the heat pipe 230.

As described above, the heat sink 240 is provided below the heat pipe 230 such that the heat exceeding the heat capacity of the heat pipe 230 is discharged to the outside of the steering wheel 20 via the heat sink 240, thereby obtaining an advantageous effect of improving performance of cooling the first thermoelectric material layer 210.

That is, at the time of cooling the surface of the steering wheel 20 by applying the current to the first thermoelectric material layer 210, one side of the first thermoelectric material layer 210 (e.g., an upper portion of the first thermoelectric material layer 210) is cooled, and the other side of the first thermoelectric material layer 210 (e.g., a lower portion of the first thermoelectric material layer 210) is heated.

In this case, the heat at the lower portion (high-temperature part) of the first thermoelectric material layer 210 is absorbed by an armature (not illustrated) in the steering wheel 20, but it is difficult to sufficiently absorb the heat, which is generated at the lower portion of the first thermoelectric material layer 210, only with the heat capacity of the armature, and as a result, there is a problem in that the performance of cooling the first thermoelectric material layer 210 deteriorates.

In contrast, according to the present disclosure, the heat sink 240 is provided below the first thermoelectric material layer 210, and the heat sink 240 may increase the heat capacity that may be insufficiently provided only by the armature in the steering wheel 20. As a result, it is possible to obtain an advantageous effect of increasing an operating time for cooling the first thermoelectric material layer 210 and improving cooling performance by minimizing a rate at which the heat of the high-temperature part of the first thermoelectric material layer 210 is transferred to the surface of the steering wheel 20 (the upper portion of the first thermoelectric material layer 210).

In addition, the first thermoelectric module 200 may include a felt layer 250 formed to cover an upper portion of the thermal diffusion layer 220.

As an example, the felt layer 250 may be made of a non-woven fabric material. According to another exemplary form of the present disclosure, the felt layer may be made of other felt materials, but the present disclosure is not restricted or limited by the type and the material of the felt layer.

As described above, the felt layer 250 is formed to cover the upper portion of the thermal diffusion layer 220, thereby obtaining an advantageous effect of improving a gripping property of the steering wheel 20. Further, a leather layer (not illustrated) may be formed on an outer surface of the felt layer 250.

The second thermoelectric module 300 is mounted in a seat 30 of the vehicle and configured to be selectively heated or cooled by being controlled by the integrated control unit 100.

Here, the configuration in which the second thermoelectric module 300 is mounted in the seat 30 of the vehicle is defined as including both a case in which the second thermoelectric module 300 is mounted in the seat 30 and a case in which the second thermoelectric module 300 is mounted on an outer surface of the seat 30.

As an example, the second thermoelectric modules 300 may be mounted in a bottom seat (buttock seat) and a backrest seat that constitute the seat 30.

The second thermoelectric module 300 may have various structures capable of being heated or cooled by being supplied with power, but the present disclosure is not restricted or limited by the structure of the second thermoelectric module 300.

As an example, the second thermoelectric module 300 includes a first layer 310 provided in the seat 30, a second thermoelectric material layer 320 disposed on an upper surface of the first layer 310, a second layer 330 disposed to cover the second thermoelectric material layer 320, and a flexible support layer 340 disposed between the first layer 310 and the second layer 330 and configured to support unit thermoelectric materials.

The first layer 310 is provided in the seat 30 to support a lower portion of the second thermoelectric material layer 320.

Particularly, the first layer 310 is made of a material capable of absorbing heat generated at the second thermoelectric material layer 320. As an example, the first layer 310 may be made of a phase change material (PCM).

The second thermoelectric material layer 320 may be formed by arranging, in a predetermined pattern, the multiple unit thermoelectric materials in which N-type thermoelectric materials 322 and P-type thermoelectric materials 324, which have opposite polarities, are connected with electrodes 326 and 328.

As an example, the second thermoelectric material layer 320 includes the N-type thermoelectric materials 322 and the P-type thermoelectric materials 324. The second thermoelectric material layer 320 includes: the multiple unit thermoelectric materials (not illustrated) arranged on an upper surface of the first layer 310; first electrodes 326 each electrically connected to one end of the N-type thermoelectric material 322 of any one of the adjacent unit thermoelectric materials and to one end of the P-type thermoelectric material 324 of the other of the adjacent unit thermoelectric materials; and second electrodes 328 each electrically connected to the other end of the N-type thermoelectric material 322 and the other end of the P-type thermoelectric material 324 that constitute the unit thermoelectric materials.

The flexible support layer 340 is provided between the first layer 310 and the second layer 330 to elastically support the second thermoelectric material layer 320 so that the second thermoelectric material layer 320 may be bent by the contact with a user's body.

As an example, the flexible support layer 340 is made of a polydimethylsiloxane (PDMS) material.

As described above, since the second thermoelectric material layer 320 is elastically supported by the flexible support layer 340 made of polydimethylsiloxane (PDMS) which is one of the flexible materials, the second thermoelectric material layer 320 may be freely bent by the contact with the user's body.

The second layer 330 is disposed to cover the second thermoelectric material layer 320.

As an example, the second layer 330 may be made of a woven fabric material and configured to form the outer surface of the seat 30.

In the exemplary form of the present disclosure, the second layer 330 supports the upper portion of the second thermoelectric material layer 320 and forms the outer surface of the seat 30. However, according to another exemplary form of the present disclosure, the second layer may be formed separately from the outer surface of the seat.

Particularly, the second layer 330 is made of a woven fabric material to improve heat transfer performance while enhancing a seating property of the seat 30.

In addition, a buffer layer 350 may be provided below the second layer 330 to improve a cushioning property. As an example, the buffer layer 350 may be made of a typical foam material.

The integrated control unit 100 is provided to integrally control the air conditioning unit 10, the first thermoelectric module 200, and the second thermoelectric module 300.

More specifically, the integrated control unit 100 controls a temperature of the first thermoelectric module 200 and a temperature of the second thermoelectric module 300 based on the thermal demand value for performing the fully automatic temperature control (FATC) of the air conditioning unit 10.

Particularly, based on a predetermined reference thermal demand range, the integrated control unit 100 is configured to cool or heat the first thermoelectric module 200 and the second thermoelectric module 300 based on the thermal demand value.

As an example, the integrated control unit 100 is configured to cool the first thermoelectric module 200 and the second thermoelectric module 300 when the thermal demand (Td) value for the fully automatic temperature control (FATC) is below the predetermined reference thermal demand range. As another example, the integrated control unit 100 is configured to heat the first thermoelectric module 200 and the second thermoelectric module 300 when the thermal demand (Td) value for the fully automatic temperature control (FATC) is above the predetermined reference thermal demand range.

For reference, the configuration in which the first thermoelectric module 200 and the second thermoelectric module 300 are controlled to be cooled means that the current is applied to the first thermoelectric module 200 and the second thermoelectric module 300 under a condition of cooling the first thermoelectric module 200 and the second thermoelectric module 300.

In addition, the configuration in which the first thermoelectric module 200 and the second thermoelectric module 300 are controlled to be heated means that the current is applied to the first thermoelectric module 200 and the second thermoelectric module 300 under a condition of heating the first thermoelectric module 200 and the second thermoelectric module 300.

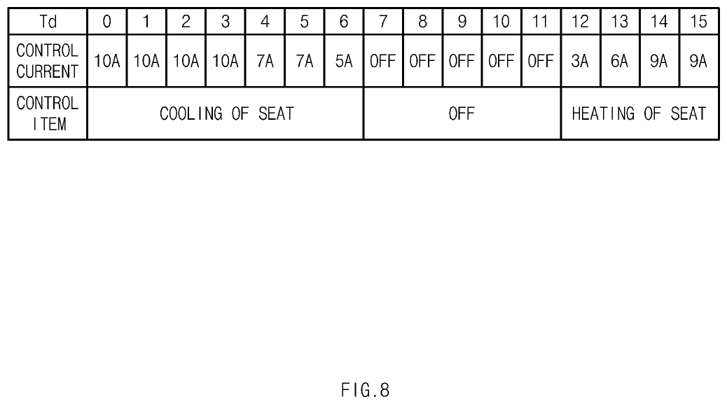

As an example, referring to FIG. 8, when the thermal demand (Td) value for the fully automatic temperature control of the air conditioning unit 10 is defined as being in 0th to 15th sections, the reference thermal demand range of the second thermoelectric module 300 may be defined as being in 7th to 11th sections. Therefore, the second thermoelectric module 300 may be controlled to be cooled when the thermal demand (Td) value is below the reference thermal demand range (0th to 6th sections), and the second thermoelectric module 300 may be controlled to be heated when the thermal demand (Td) value is above the reference thermal demand range (12th to 15th sections). Further, when the thermal demand (Td) value is within the reference thermal demand range (7th to 11th sections), the supply of power to the second thermoelectric module 300 is cut off

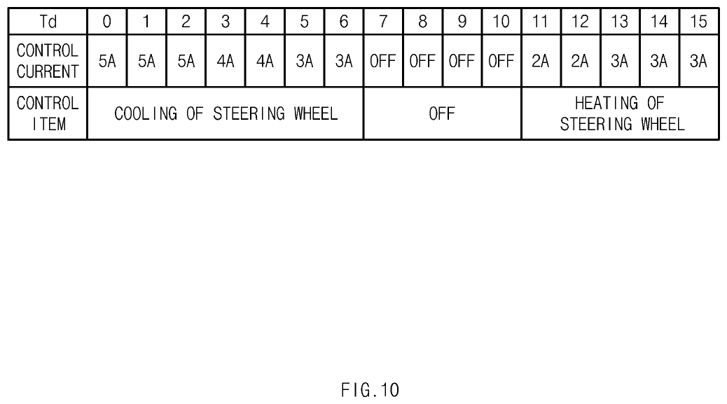

As another example, referring to FIG. 10, when the thermal demand (Td) value for the fully automatic temperature control of the air conditioning unit 10 is defined as being in the 0th to 15th sections, the reference thermal demand range of the first thermoelectric module 200 may be defined as being in the 7th to 10th sections. Therefore, the first thermoelectric module 200 may be controlled to be cooled when the thermal demand (Td) value is below the reference thermal demand range (0th to 6th sections), and the first thermoelectric module 200 may be controlled to be heated when the thermal demand (Td) value is above the reference thermal demand range (11th to 15th sections). Further, when the thermal demand (Td) value is within the reference thermal demand range (7th to 10th sections), the supply of power to the first thermoelectric module 200 is cut off

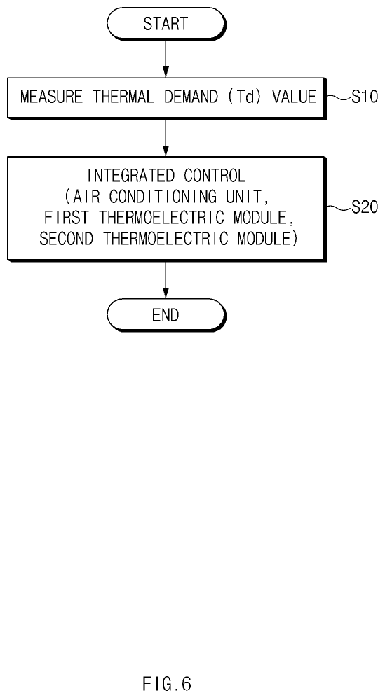

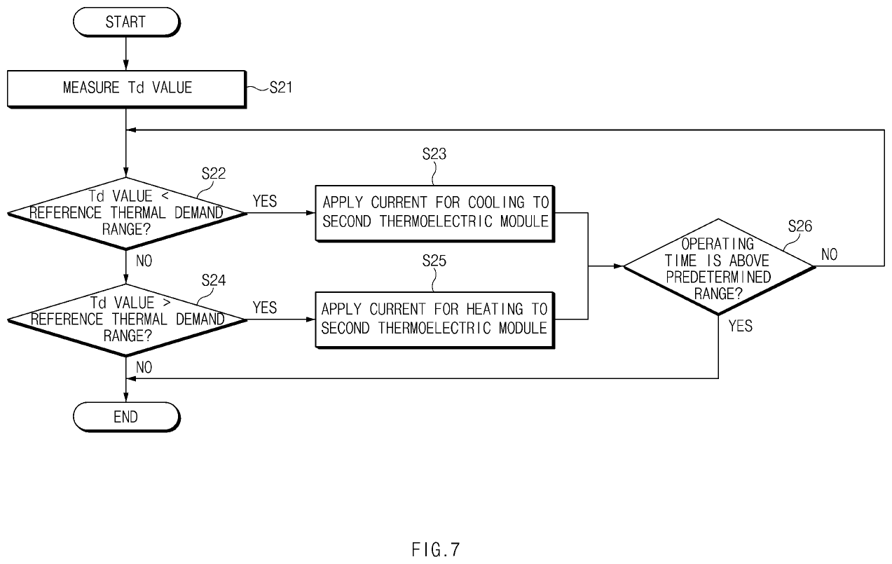

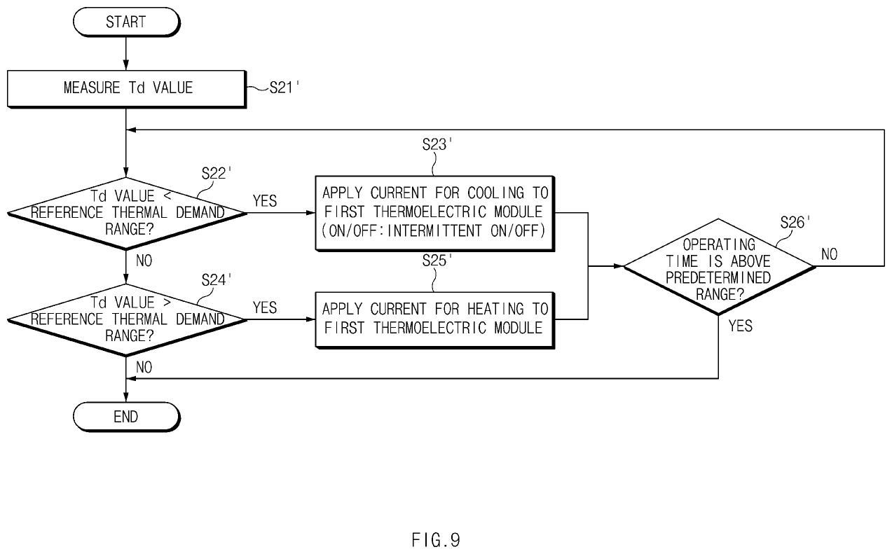

Meanwhile, FIG. 6 is a block diagram illustrating a method of controlling the vehicle temperature control system according to one form of the present disclosure, FIGS. 7 and 8 are views for explaining a process of operating the second thermoelectric module, as a method of controlling the vehicle temperature control system according to another form of the present disclosure, and FIGS. 9 and 10 are views for explaining a process of operating the first thermoelectric module, as the method of controlling the vehicle temperature control system according to one form of the present disclosure. Further, the parts identical and corresponding to the parts in the above-mentioned configuration will be designated by the identical or corresponding reference numerals, and detailed descriptions thereof will be omitted.

Referring to FIG. 6, in the vehicle temperature control system which includes: the air conditioning unit 10 configured to cool and heat the interior of the vehicle; the first thermoelectric module 200 mounted in the steering wheel 20 of the vehicle and configured to be selectively heated or cooled; and the second thermoelectric module 300 mounted in the seat 30 of the vehicle and configured to be selectively heated or cooled, the vehicle temperature control system is controlled according to a method including: a measurement step S10 of measuring the thermal demand (Td) value for the fully automatic temperature control (FATC) of the air conditioning unit 10; and a control step S20 of integrally controlling the air conditioning unit 10, the first thermoelectric module 200, and the second thermoelectric module 300 based on the thermal demand value.

First, the thermal demand (Td) value for the fully automatic temperature control (FATC) of the air conditioning unit 10 is measured (S10).

Here, the thermal demand (Td) value refers to a default value used for performing the fully automatic temperature control by the air conditioning unit. The thermal demand value may be determined by calculating the amount of change in accordance with the change in inside air temperature (indoor temperature) and outside air temperature.

Next, the air conditioning unit 10, the first thermoelectric module 200, and the second thermoelectric module 300 are integrally controlled based on the measured thermal demand (Td) value (S20).

Particularly, in the control step, the first thermoelectric module 200 and the second thermoelectric module 300 are controlled based on the thermal demand (Td) value for the fully automatic temperature control of the air conditioning unit 10.

As described above, the air conditioning unit is controlled and the first thermoelectric module 200 and the second thermoelectric module 300 are controlled together based on the thermal demand (Td) value, thereby obtaining an advantageous effect of quickly establishing a comfortable traveling environment and reducing or minimizing unnecessary power consumption.

More specifically, in the control step S20, the first thermoelectric module 200 and the second thermoelectric module 300 are configured to be cooled or heated based on the thermal demand value detected based on the predetermined reference thermal demand range.

As an example, in the control step S20, the first thermoelectric module 200 and the second thermoelectric module 300 are controlled to be cooled when the thermal demand (Td) value for the fully automatic temperature control (FATC) is below the predetermined reference thermal demand range, and the first thermoelectric module 200 and the second thermoelectric module 300 are controlled to be heated when the thermal demand (Td) value for the fully automatic temperature control (FATC) is above the predetermined reference thermal demand range.

Referring to FIGS. 7 and 8, in the control step S20, the second thermoelectric module 300 (seat) is configured to be cooled or heated based on the thermal demand value detected based on the predetermined reference thermal demand range.

For reference, the thermal demand (Td) value for the fully automatic temperature control of the air conditioning unit 10 may be defined as being in the 0th to 15th sections, and the reference thermal demand range in respect to the second thermoelectric module 300 may be defined as being in 7th to 11th sections.

First, the thermal demand (Td) value is measured (S21).

Next, when it is detected that the thermal demand (Td) value is below the reference thermal demand range (S22) as a result of comparing the thermal demand (Td) value with the reference thermal demand range, the current for a cooling operation is applied to the second thermoelectric module 300 (S23).

In contrast, when it is detected that the thermal demand (Td) value is above the reference thermal demand range (S24) as a result of comparing the thermal demand (Td) value with the reference thermal demand range, the current for a heating operation is applied to the second thermoelectric module 300 (S25).

Particularly, in the control step, when the operating time (current applying time) for cooling and heating the second thermoelectric module 300 is above a predetermined operating time range, the operation of the second thermoelectric module 300 is stopped (S26).

As described above, the operation of the second thermoelectric module 300 is stopped when the operating time for cooling and heating the second thermoelectric module 300 is above the predetermined operating time range (e.g., 20 to 30 minutes), thereby obtaining an advantageous effect of preventing the second thermoelectric module 300 from being overheated and overcooled and inhibiting or minimizing injuries to the occupant (e.g., burns) caused by overheating.

Referring to FIGS. 9 and 10, in the control step S20, the first thermoelectric module 200 (steering wheel) is configured to be cooled or heated based on the thermal demand value detected based on the predetermined reference thermal demand range.

For reference, the thermal demand (Td) value for the fully automatic temperature control of the air conditioning unit 10 may be defined as being in the 0th to 15th sections, and the reference thermal demand range in respect to the first thermoelectric module 200 may be defined as being in the 7th to 10th sections.

First, the thermal demand (Td) value is measured (S21′).

Next, when it is detected that the thermal demand (Td) value is below the reference thermal demand range (S22′) as a result of comparing the thermal demand (Td) value with the reference thermal demand range, the current for the cooling operation is applied to the first thermoelectric module 200 (S23′).

In contrast, when it is detected that the thermal demand (Td) value is above the reference thermal demand range (S24′) as a result of comparing the thermal demand (Td) value with the reference thermal demand range, the current for the heating operation is applied to the first thermoelectric module 200 (S25′).

Particularly, in the control step, when the operating time (current applying time) for cooling and heating the first thermoelectric module 200 is above the predetermined operating time range, the operation of the first thermoelectric module 200 is stopped (S26′).

As described above, the operation of the first thermoelectric module 200 is stopped when the operating time for cooling and heating the first thermoelectric module 200 is above the predetermined operating time range (e.g., 20 to 30 minutes), thereby obtaining an advantageous effect of preventing the first thermoelectric module 200 from being overheated and overcooled and inhibiting or minimizing injuries to the occupant (e.g., burns) caused by overheating.

More particularly, in the control step, the operation of cooling the first thermoelectric module 200 is intermittently turned on or off.

Here, the configuration in which the operation of cooling the first thermoelectric module 200 is intermittently turned on or off means that the current for the cooling operation is intermittently applied to the first thermoelectric module 200.

This configuration is based on the fact that the heat pipe and the heat sink 240, which treat and discharge the heat generated at the high-temperature part of the first thermoelectric module 200, have restrictive heat capacities due to the structural restriction of the steering wheel 20. The operation of cooling the first thermoelectric module 200 is intermittently turned on or off, thereby obtaining an advantageous effect of reducing or minimizing deterioration in cooling performance caused by deterioration in heat discharging properties of the first thermoelectric module 200.

As an example, when the operating time for cooling the first thermoelectric module 200 exceeds 5 minutes, the operation of cooling the first thermoelectric module 200 may be turned off for 5 minutes.

Meanwhile, whether to integrally control the air conditioning unit 10, the first thermoelectric module 200, and the second thermoelectric module 300 may be determined by preferentially considering control specifications related to safety of the vehicle. In addition, the process of integrally controlling the air conditioning unit 10, the first thermoelectric module 200, and the second thermoelectric module 300 may be stopped when an outside temperature sensor and an internal temperature sensor of the vehicle are broken down, and whether to perform the integrated control in an ignition-on (key-on) state may be determined by user settings.

While the present disclosure has been described above with reference to the exemplary forms, it may be understood by those skilled in the art that the present disclosure may be variously modified and changed without departing from the spirit and scope of the present disclosure disclosed in the claims.

What is claimed is:

1. A vehicle temperature control system comprising:
an air conditioning unit configured to cool and heat an interior of a vehicle;
a first thermoelectric module mounted in a steering wheel of the vehicle and configured to be selectively heated or cooled;
a second thermoelectric module mounted in a seat of the vehicle and configured to be selectively heated or cooled; and
an integrated control unit configured to integrally control the air conditioning unit, the first thermoelectric module, and the second thermoelectric module.

2. The vehicle temperature control system of claim 1, wherein the integrated control unit is configured to control a temperature of the first thermoelectric module and a temperature of the second thermoelectric module based on a thermal demand (Td) value for fully automatic temperature control (FATC) of the air conditioning unit.

3. The vehicle temperature control system of claim 2, wherein the integrated control unit is configured to cool the first thermoelectric module and the second thermoelectric module when the thermal demand value is below a predetermined reference thermal demand range, and the integrated control unit is configured to heat the first thermoelectric module and the second thermoelectric module when the thermal demand value is above the predetermined reference thermal demand range.

4. The vehicle temperature control system of claim 1, wherein the first thermoelectric module comprises:
a first thermoelectric material layer mounted in the steering wheel;
a thermal diffusion layer configured to cover the first thermoelectric material layer;
a heat pipe provided below the first thermoelectric material layer; and
a heat sink provided below the heat pipe.

5. The vehicle temperature control system of claim 4, further comprising:
a felt layer configured to cover the thermal diffusion layer.

6. The vehicle temperature control system of claim 4, wherein the heat pipe is made of a phase change material (PCM).

7. The vehicle temperature control system of claim 1, wherein the second thermoelectric module comprises:
a first layer provided in the seat;
a second thermoelectric material layer disposed on an upper surface of the first layer;
a second layer disposed to cover the second thermoelectric material layer; and
a flexible support layer disposed between the first layer and the second layer and configured to support the second thermoelectric material layer.

8. The vehicle temperature control system of claim 7, wherein the flexible support layer is made of a polydimethylsiloxane (PDMS) material.

9. The vehicle temperature control system of claim 7, wherein the first layer is made of a phase change material (PCM).

10. A method of controlling a vehicle temperature control system: the control system including an air conditioning unit configured to cool and heat an interior of a vehicle, a first thermoelectric module mounted in a steering wheel of the vehicle and configured to be selectively heated or cooled, and a second thermoelectric module mounted in a seat of the vehicle and configured to be selectively heated or cooled, the method comprising:
a measurement step of measuring a thermal demand value for fully automatic temperature control (FATC) of the air conditioning unit; and
a control step of integrally controlling the air conditioning unit, the first thermoelectric module, and the second thermoelectric module based on the thermal demand value.

11. The method of claim 10, wherein in the control step, a temperature of the first thermoelectric module and a temperature of the second thermoelectric module are controlled based on the thermal demand value.

12. The method of claim 11, wherein in the control step, the first thermoelectric module and the second thermoelectric module are cooled when the thermal demand value is below a predetermined reference thermal demand range, and the first thermoelectric module and the second thermoelectric module are heated when the thermal demand value is above the predetermined reference thermal demand range.

13. The method of claim 12, wherein in the control step, an operation of the second thermoelectric module stops when an operating time for cooling and heating the second thermoelectric module is above a predetermined operating time range.

14. The method of claim 12, wherein in the control step, an operation of the first thermoelectric module stops when an operating time for cooling and heating the first thermoelectric module is above a predetermined operating time range.

15. The method of claim 14, wherein in the control step, an operation of cooling the first thermoelectric module intermittently turns on or off.
